(19) United States
(12) Patent Application Publication
(10) Pub. No.: US 2007/0189349 A1
(43) Pub. Date: Aug. 16, 2007

(54) Single mode laser

(76) Inventors: John A. Patchell, Dublin (IE); Brian J. Kelly, Dublin (IE); James C. O'Gorman, Dublin (IE)

Correspondence Address: BROOKS & CAMERON, PLLC, 1221 NICOLLET MALL #500, MINNEAPOLIS, MN, 55403, US

(21) Appl. No.: 11/656,931

(22) Filed: Jan. 23, 2007

Related U.S. Application Data
(63) Continuation of application No. PCT/EP05/53392, filed on Jul. 14, 2005.

(30) Foreign Application Priority Data
Jul. 23, 2004 (IE) S2004/0497

(51) Int. Cl. H01S 5/00

(52) U.S. Cl. 372/49.01

(57) ABSTRACT

A laser comprising a lasing cavity, having a lasing medium and primary optical feedback means in the form of a facet at either end of the cavity is described. The laser includes secondary optical feedback means in the form of one or more effective refractive index perturbations in the lasing cavity with at least one of the facets configured to preferentially reflects a specific wavelength or band of wavelengths. A method of manufacturing such a laser is also described as is a method of suppressing side modes in a lasing device.

### FIELD OF THE INVENTION

The present invention relates to a single mode laser, in particular a single mode slotted laser comprising a facet coating for additional side mode suppression. The invention further relates to a method of manufacturing a single mode slotted laser and a method of side mode suppression in a slotted laser.

### BACKGROUND

Fabry Perot laser diodes containing discrete refractive index perturbations have being shown to operate in a single longitudinal mode over a wide temperature range, see EP 1 214 763 (Trinity College Dublin) and IE S2003/0516 (Eblana Photonics Limited) the contents of which are incorporated herein by reference. So called “slotted lasers”, which achieve single longitudinal mode emission by means of optical feedback resulting from the formation of slot features along the laser cavity, are also disclosed in Irish Patent No S82521 (National University of Ireland, Cork).

For ease of description the term “slot” will be taken to include a slot etched, or otherwise formed, in a part of the laser cavity as well as any other form of discrete refractive index perturbation which has the effect of modifying optical feedback within the cavity. Suitable such refractive index perturbation means are disclosed in the prior art cited above.

Typically the wider the temperature range which the device is expected to work over the greater the level of optical feedback which required from the slot features. However the introducing slot features which are capable of providing optical feedback is accompanied by an increase in the internal loses of the laser diode. This is an undesirable effect, the primary result of which is to lower the slope efficiency of the laser diode in question. In order to minimise internal loses it is therefore appropriate to keep the number of etch slot features to a minimum. This requires a slot pattern that provides just enough optical feedback to ensure that the laser operates in a single longitudinal mode over the temperature range of interest.

It is an object of the present invention to address the difficulties which arise in balancing the internal loses arising from the incorporation of slots with the need for sufficient optical feedback within the laser cavity.

It is further object of the invention to provide a slotted laser which allows greater flexibility in slot pattern design taking into account the difficulties set out above.

### BRIEF DESCRIPTION OF THE INVENTION

Accordingly the invention provides a laser in accordance with claim 1 with advantageous embodiments detailed in dependent claims thereto. The invention also provides a method of forming a laser in accordance with claim 9 and a method of suppressing side modes in accordance with claim 10.

In accordance with a first embodiment, the present invention provides a laser emitting light of substantially a single wavelength comprising: a lasing cavity, having a lasing medium and primary optical feedback means in the form of a facet at either end of the cavity; and secondary optical feedback means in the form of one or more effective refractive index perturbations in the lasing cavity; wherein at least one of the facets preferentially reflects a specific wavelength or band of wavelengths.

Either or both of the facets may comprise a coating which preferentially reflects a desired wavelength or band of wavelengths.

Suitably either or both facets may comprise a coating formed from one or more layers of material selected from the group consisting of SiO₂, TaO₂, Si, Al₂O₃ and mixtures thereof.

Preferably, either or both facets are adapted to preferentially reflect light at the wavelength the laser is designed to emit at.

The invention also provides a method of manufacturing a laser emitting light of substantially a single wavelength comprising the steps of:

forming a lasing cavity, having a lasing medium and primary optical feedback means in the form of a facet at either end of the cavity; forming secondary optical feedback means in the form of one or more effective refractive index perturbations in the lasing cavity; and applying to at least one of the facets a coating which preferentially reflects a specific wavelength or band of wavelengths.

The present invention further provides a method of suppressing side modes in a slotted laser emitting light of substantially a single wavelength (single mode) comprising the step of applying a coating to either or both facets of a laser, wherein said coating preferentially reflects a specific wavelength or band of wavelengths.

### DESCRIPTION OF THE DRAWINGS

The invention is described in detail below with reference to the accompanying drawings in which:

FIGS. 1 and 2 illustrate the effect of index perturbation and confinement factor on a guided mode within a laser cavity;

FIG. 3 illustrates the structure and refractive index profile of a coating consisting of four half wave layers;

FIG. 4 shows the calculated mirror loss profile of a laser with an uncoated output facet;

FIG. 5 shows the calculated mirror loss profile of a laser according to the invention with an output facet coated with four half wave layers;

FIG. 6 shows the calculated mirror loss profile of a laser according to the invention with an output facet coated with three half wave layers;

FIG. 7 show the calculated mirror loss profile of a laser according to the invention with an output facet coated with a four layer coating;

FIG. 8 shows the structure and refractive index profile of a coating consisting of three half wave layers; and

FIG. 9 shows the structure and refractive index profile of a four layer coating.

### DETAILED DESCRIPTION

In order to provide more flexibility in slotted laser design while taking into account the internal loses arising as a result of the incorporation of slots, the present invention provides a means of facilitating a reduction in the level optical feedback which is needed from the slot pattern in order to achieve single mode operation over a specified temperature range. This in turn leads to higher slope efficiencies, and ultimately to greater output powers from uncooled laser diodes containing slot features.

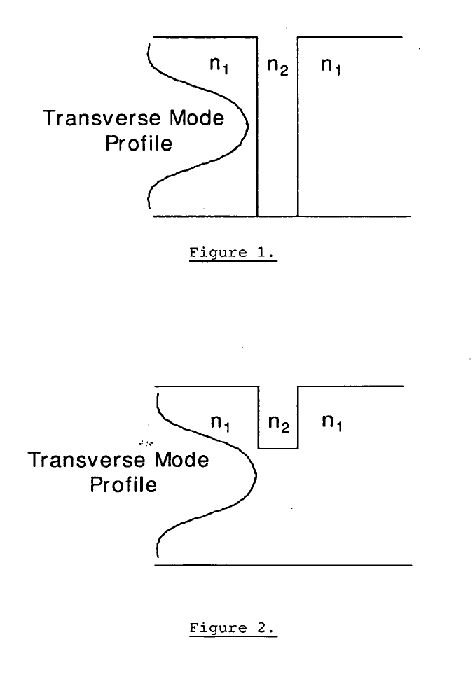

It has been shown (“Deep-Etched Distributed Bragg Reflector Lasers with curved mirrors—Experiments and Modeling”—IEEE Journal of Quantum Electronics, Vol. 37, No. 6, June 2001, Modh et al) that the ratio of reflected to scattered power is far larger for index changes that have a confinement factor of 1.0 with the guided mode (FIG. 1), than for index changes whose percentage overlap with the guided mode profile is less than 0.5 (FIG. 2). The index changes associated with optical facet coatings have a confinement factor of 1.0 with the guided mode whereas the etched slot features that are used to perturb the guided mode typically have a confinements factors far less than 0.5.

The basis of the present invention is the finding that the above effect can be used to complement the optical feedback which is provided by a pattern of etched slot features. More specifically the mirror loss spectra of a laser diode can be more efficiently manipulated by the combination of an appropriate pattern of slot features and suitable facet coatings, rather than a pattern of slot features alone. Furthermore such coatings are especially appropriate for use in conjunction a discrete number of etched slot features, since, in these structures, the longitudinal modes are determined by the laser facets and the coatings which are applied to them. Therefore, the mirror loss profiles of the coatings applied to either facet will be almost independent of cleave accuracy and cavity length. This is not the case in DFB laser, since in such devices the primary source of feedback is provided by the grating and not the cavity mirrors. In order to complement the mirror loss profile of the slot pattern the reflectivity spectra of coatings used preferably have a global or local maxima at, or near, the design wavelength of the laser diode. Other factors that may affect the efficiency and the effectiveness of a particular coating design are thickness of the coating and relative curvature of the reflectivity spectrum with respect to wavelength. The thickness of the coating should preferably be kept as thin as possible in order to minimise both the scattering loses within the coating itself and the stress placed upon the laser facet. Furthermore it is preferable to have the relative curvature of the reflectivity spectrum high enough to discriminate against the presence of unwanted side modes.

The facet coatings typically comprise one or more layers, the imaginary refractive index of which is negligible at the wavelength of interest (in other words there is no loss due to absorption by the coating material, ie the band gap of the material is greater than the design wavelength of the device) and which can be controllably deposited on the laser facets using available coating technologies. Suitable such materials include for example SiO₂, TaO₂, Si, Al₂O₃ and mixtures thereof.

A laser according to the invention may be produced by forming a lasing cavity, having a lasing medium and primary optical feedback means in the form of a facet at either end of the cavity; forming secondary optical feedback means in the form of one or more effective refractive index perturbations in the lasing cavity; and applying to at least one of the facets a coating which preferentially reflects a specific wavelength or band of wavelengths. Such a process may typically involve some or all of the following processing steps:
Growth of an AlInGaAs/InP epitaxial laser diode structure on an InP substrate;
Formation of a resist pattern for ridge/slot features using standard lithographic techniques;
Etching the ridge and slot features;
Application of a dielectric coating;
Etching an opening in the dielectric along the top of the ridge structures;
Deposition of contact metal;
Cleaving into bar format;
Application of facet coating(s); and
Singulation into individual devices.

In the description of specific embodiments that follows, it is only a coating on the output facet of the laser together with the etched slot features that are used alter the shape mirror loss spectra of the device. However, coatings on either or both facets of the laser may be used to adapt the mirror loss spectra of the device. Also within the scope of the invention are any and all lasers diodes containing discrete features that locally perturb the effective index of the guided mode, coated in such a way that the mirror loss spectra of the coating and that of the laser complement each other. Lasers according to the invention facilitate single mode operation over wider temperatures ranges than would otherwise be possible and enhance output power.

The coating may comprise one or more layers which may be formed of any material or combination of materials which provide selective or preferential reflection of the wavelength or wavelengths desired.

A first embodiment of the invention employs a class of coatings which comprises one or more layers whose thickness, d, is given by

$$d = \frac{λ}{2 n} .$$

In this equation λ is the free space wavelength of the laser light and n is the refractive index of the coating layer in question. Layers whose thicknesses obey the above criteria are termed “half wave layers” since their thicknesses are equal in length to half the wavelength of light in that particular material. Due to the previously discussed considerations regarding coating thickness and facet stress, it is less preferred to consider coatings with more than ten such layers. Other embodiments may use a multiple of “2n” as the denominator in the above equation.

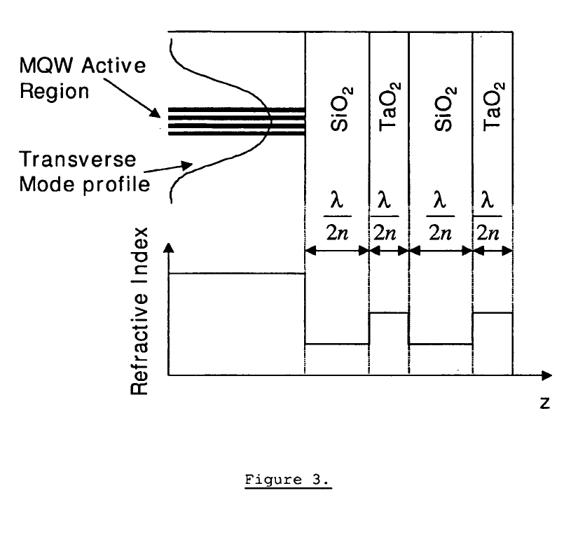

FIG. 3 shows the structure and refractive index profile of a coating designed to have a reflectivity maximum at λ=1.49 μm, which consists of four such layers (“half wave” layers). In this particular coating the high and low index layers are formed from TaO₂ and SiO₂ respectively. However it is possible to achieve the same effect using other materials fulfilling the reflectivity and processability criteria listed above, for example Si, Al₂O₃ and similar materials.

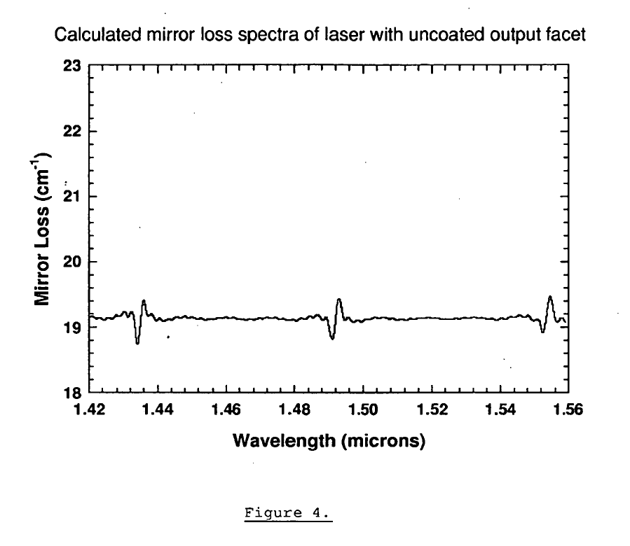

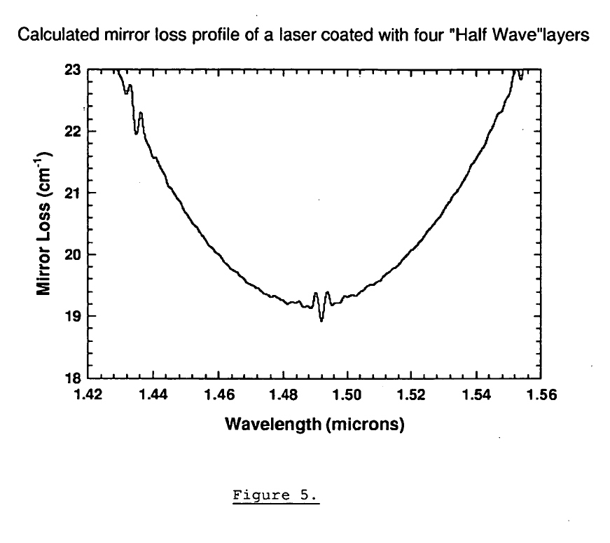

FIG. 4 shows the calculated mirror loss spectra of a 350 micron long AlGaInAs/InP slotted laser designed for emission at 1.49 μm whose output facet is uncoated. The slot pattern itself consisted of 19 tapered slots separated by twelve and a half material design wavelengths, with the optically active interface of the closest slot to the front facet being located 40 microns from that facet. FIG. 5 shows the calculated mirror loss spectra of an identical laser whose output facet is coated with the structure detailed in FIG. 3. The same coating was applied to the back facets of both lasers, this coating had a reflectivity of 95% at the design wavelength of the laser. However since the reflectivity of this coating is almost independent of wavelength, around the design wavelength, it has a negligible effect on the shape of the mirror loss spectrum in this wavelength interval. While the above design is easy to implement it is not optimal in the sense that, coatings with high curvatures can only be achieved by using relatively thick coatings.

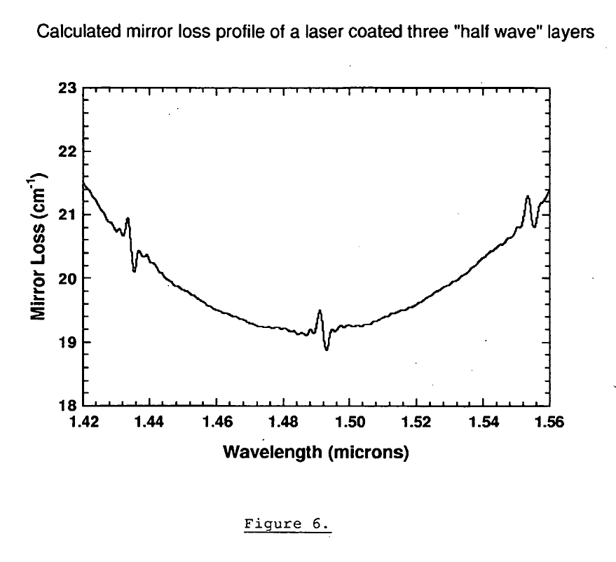

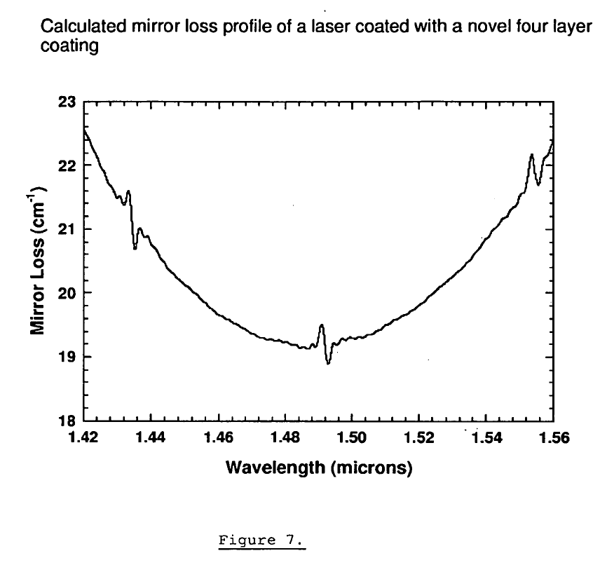

The present invention also incorporates coatings which have a larger relative curvature for a given thickness of coating material compared to the “half wave design” discussed above. To illustrate this point the calculated mirror loss spectra for two lasers according to the invention are shown in FIGS. 6 and 7. These device designs are identical in every respect to those discussed above except that they have different optical coatings applied to their output facets.

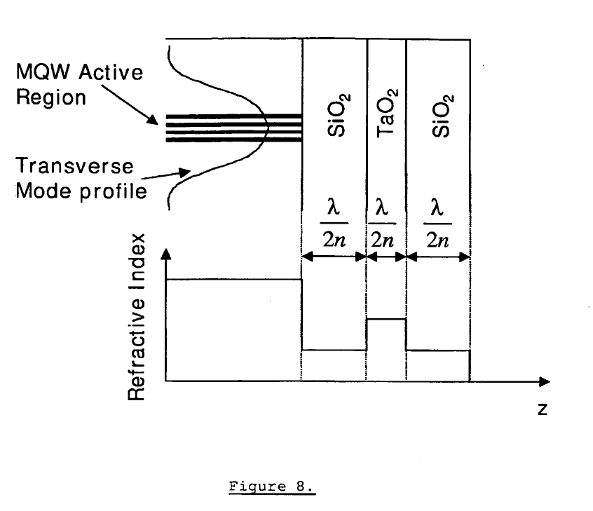

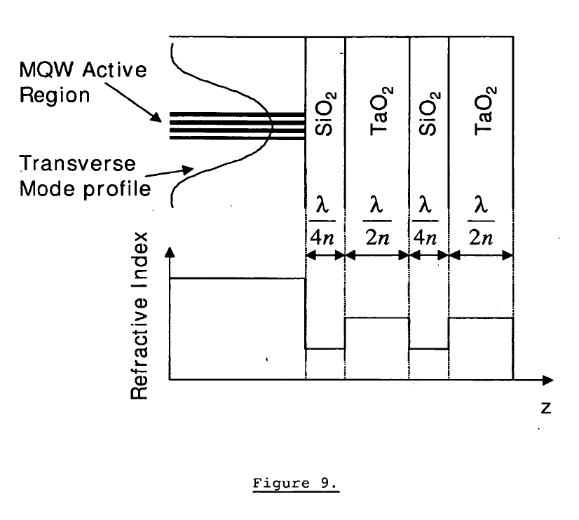

The first instance (FIG. 6) relates to a device whose facet is coated with three “half wave” layers. The structure of this coating is shown in FIG. 8. Total thickness of the coating is 1.38 μm. A further embodiment is depicted in FIG. 7 which shows a calculated mirror loss profile of a laser diode whose output face is coated with a novel four layer coating. FIG. 9 (total thickness of the coating is 1.22 μm) shows the corresponding structure of this coating in which the coating comprises a series of “quarter wave”, “half wave” pairs. Preferably, the “half wave” layers in this structure are composed of the high index material, whereas the “quarter wave” layers are preferably made of low index material. This arrangement helps minimise the thickness of the coating.

It is clear from FIGS. 6 and 7, that the four layer coating disclosed has a greater curvature than the structure consisting of three “half wave” layers, moreover this is achieved using a coating design the thickness of which is less than that of the triple “half wave” coating for any given wavelength.

The invention has been described with regard to preferred embodiments which, it will be appreciated, are illustrative of the invention and are not intended to limit the invention in any way. It will be appreciated that modifications can be made to the described exemplary embodiments without departing from the spirit and scope of the invention and it is not intended that the invention be limited in any way except as may be deemed necessary in the light of the appended claims. Furthermore the words comprises/comprising when used in this specification are to specify the presence of stated features, integers, steps or components but does not preclude the presence or addition of one or more other features, integers, steps, components or groups thereof.

1. A semiconductor laser comprising: a lasing cavity, having a lasing medium and primary optical feedback features in the form of a facet at either end of the cavity; and secondary optical feedback features in the form of one or more effective refractive index perturbations in the lasing cavity; wherein at least one of the facets preferentially reflects a specific wavelength or band of wavelengths.

2. A laser according to claim 1 wherein either or both facets comprise a coating provided thereon.

3. A laser according to claim 2 wherein the coating is provided by a material having a reflectivity spectrum corresponding to the desired specific wavelength or band of wavelengths to be reflected from the at least one of the facets.

4. A laser according to claim 2 where, the coating being chosen is selected from at least one material having a reflectivity spectrum specific to reflect a desired specific wavelength or band of wavelengths.

5. A laser according to claim 2 wherein the coating comprises one or more layers whose thickness, d, is given by
$$d = \frac{λ}{2 n} and \text{/} or d = \frac{λ}{4 n} .$$
where λ is the free space wavelength of the laser and n is the refractive index of the coating layer in question.

6. A laser according to claim 1 wherein the coating has a reflectivity spectrum with curvature high enough to discriminate against the presence of unwanted side modes.

7. A laser according to claim 2 wherein the coating is formed from one or more layers of material selected from the group consisting of SiO₂, TaO₂, Si, Al₂O₃ and mixtures thereof.

8. A laser according to claim 1 wherein either or both facets are adapted to preferentially reflect light at the design wavelength of the laser.

9. A method of manufacturing a laser comprising the steps of:
(a) forming a lasing cavity, having a lasing medium and primary optical feedback features in the form of a facet at either end of the cavity;
(b) forming secondary optical feedback features in the form of one or more effective refractive index perturbations in the lasing cavity; and
(c) applying to at least one of the facets a coating which preferentially reflects a specific wavelength or band of wavelengths.

10. A method of suppressing side modes in a slotted laser emitting light of substantially a single wavelength (single mode) comprising the step of applying a coating to either or both facets of a laser, wherein said coating preferentially reflects a specific wavelength or band of wavelengths.
